(19) United States
(12) Patent Application Publication
(10) Pub. No.: US 2001/0005147 A1
(43) Pub. Date: Jun. 28, 2001

(54) Semiconductor circuit including output buffer circuit and drive circuit for driving output buffer circuit

(75) Inventor: Tetsuya Ootsuki, Tokyo (JP)

Correspondence Address: HELFGOTT & KARAS, P.C., 60th FLOOR, EMPIRE STATE BUILDING, NEW YORK, NY, 10118, US

(73) Assignee: NEC CORP

(21) Appl. No.: 09/749,085

(22) Filed: Dec. 27, 2000

(30) Foreign Application Priority Data
Dec. 27, 1999 (JP) 370606/1999

(51) Int. Cl. H03K 19/094

(52) U.S. Cl. 326/83

(57) ABSTRACT

A semiconductor circuit is composed of an N-channel transistor, a driving circuit, and a charge pump. The N-channel transistor includes a gate and a drain. The drain is provided with a power supply potential. The driving circuit sets a gate potential at the gate to a first potential in response to an input signal. The charge pump raises the gate potential to a second potential higher than the first potential in response to the input signal.

### BACKGROUND OF THE INVENTION

1. Field of the Invention

This invention relates to a semiconductor circuit. More particularly, it relates to a semiconductor circuit that includes an output buffer circuit and a drive circuit for driving the output buffer circuit.

2. Description of the Related Art

In recent years, a circuit including a pair of n-channel transistors connected between the power source and the ground potential is used as output buffer circuit in certain occasions. Here, the circuit is referred to as “NMOS buffer circuit” hereinafter. An NMOS buffer circuit, which include no P-channel MOS transistor, has an advantage that it shows a high drive potential. Also, the NMOS buffer circuit has another advantage that it is not necessary to form a well for producing a p-channel MOS transistor, which reduces the number of wells.

The NMOS buffers circuits are accompanied by a problem that the output voltage is lower than the gate voltage by the threshold voltage of the n-type transistors. Therefore, the gate voltage is generally boosted.

Japanese Laid Open Patent Application (Jp-A-Showa 60-83297) discloses such an NMOS buffer circuit. FIG. 1 shows a schematic circuit diagram of the known NMOS buffer circuit. Referring to FIG. 1, the known NMOS buffer circuit includes a MOS transistor 101 and a MOS transistor 102. The gate of the MOS transistor 101 is connected to an input terminal to which a drive signal φ₁ is applied. The drain of the MOS transistor 101 is connected to the power supply terminal to which a power supply potential V_{CC} is applied. The source of the MOS transistor 101 is connected to an output terminal 111 that outputs an output signal φₛ.

On the other hand, the gate of the MOS transistor 102 is connected to another input terminal to which a drive signal φ₂ is applied. The source of the MOS transistor 102 is grounded (0V). The drain of the MOS transistor 102 is connected to the output terminal 111.

The output terminal 111 is connected to one of the terminal of voltage boosting capacitance 103. A voltage boosting signal φ₃ is applied to the other terminal of the voltage boosting capacitance 103. Additionally, the output terminal 111 is connected to a charge pump circuit 104. The charge pump circuit 104 includes a capacitance 106 and MOS transistors 107, 108, 109 and 110. The charge pump circuit 104 accumulates electric charge in capacitance 106 as charge is supplied from signal generator 105. Then, the charge pump circuit 104 supplies the accumulated electric charge to the output terminal by way of the MOS transistor 107.

Now, the operation of the above known NMOS buffer circuit will be described below with referring to FIG. 2. Firstly, the drive signal φ₁ rises from 0V to level “H” at time t₁ as shown in FIG. 2A. At the same time, the drive signal θ₂ falls from level “H” to 0V as shown in FIG. 2B. Then, the output signal φₛ starts rising from 0V to level “H” as shown in FIG. 2D. Then, at time t₂, the drive signal φ₁ rises to above the power supply potential V_{CC} and the output signal φₛ gets to the level of the power supply potential V_{CC}.

Thereafter, at time t₃, the drive signal φ₁ falls to 0V to turn off the MOS transistor 101. At the same time, the voltage boosting signal φ₃ rises from 0V to level “H” as shown in FIG. 2C. Subsequently, at time t₄, the output signal φₛ is boosted above the power supply potential V_{CC} by the voltage boosting capacitance 103.

Assume now that the level of the output signal falls a little from level “H” due to the leak current generated there long after the rise of the output signal φₛ as observed at time t₅. Then, after time t₅, the charge pump circuit 104 supplies the output terminal 111 with electric charge so that the output signal φₛ restores the level “H” at time t₇. In this way, the potential level “H” of the boosted output signal φₛ that is above the power supply potential V_{CC} is maintained by the charge pump circuit 104.

Also, Japanese Laid Open Patent Application (Jp-A-Heisei 7-249979) describes another known NMOS buffer circuit. The known NMOS buffer circuit includes a boosting circuit 201, an inverter IV201, an inverter IV202 and an output circuit 202 as shown in FIG. 3.

The boosting circuit 201 includes transistors Q205 to Q207, capacitors C201, C202, and an inverter IV203. The boosting circuit 201 includes a bootstrap circuit.

The output circuit 202 comprises a pair of MOS transistors Q201 and Q202 connected in series between the power supply potential V_{CC} and the ground potential GND.

When signal D0 is at level “H”, the boosting circuit 201 supplies the inverter IV201 with a potential V_{H} that is higher than the power supply potential V_{CC}. If the threshold voltage of the MOSFET Q201 is Vₜₕ,

V_{H}>V_{CC}+Vₜₕ.

The inverter IV201 is fed with a signal obtained by inverting signal D0 through the inverter IV202. If the signal D0 is at level “H”, the inverter IV201 supplies the gate of the MOS transistor Q201 with potential V_{H}. Then, the MOSFET Q201 produces output voltage Vₒᵤₜ from its source. If the signal D0 is at level “H”, the output voltage Vₒᵤₜ is lower than the gate voltage of the MOSFET Q201 by the threshold voltage of the MOSFET Q201. However, the gate of the MOSFET Q201 is supplied with potential V_{H} as described above so that the output voltage Vₒᵤₜ is higher than the power supply potential V_{CC}.

Japanese Laid Open Patent Application (Jp-A Showa 62-212997) describes still another known NMOS buffer circuit that comprises transistors Q301 through Q318, inverters N301 through N306 a boosting capacitance Cp301 and a capacitance Cp302.

The first terminal of the boosting capacitance Cp301 is precharged to potential V_{CC} by the MOSFET Q301. As the voltage of signal rasA is brought up to level “H”, the power supply potential V_{CC} is supplied to the second terminal of the boosting capacitance Cp301. Then, the potential of the first terminal of the boosting capacitance Cp301 is raised to a level about twice as high as that of the power supply potential V_{CC}. Thus, as the voltage of the signal rasA is brought up to level “H”, the MOS transistor Q302 is turned on and the potential of the output terminal φₓ is raised to a level about twice as high as that of the power supply potential V_{CC}.

The MOS transistor Q312 to Q314 and the capacitance Cp302 form a charge pump, which supplies an electric current to the output terminal φₓ. The potential of the first terminal of the capacitance Cp301 is reduced by the leak current that arises in the NMOS buffer circuit. The capacitance of the capacitance Cp302 is set to such a low level that the current feeding capacitance of the charge pump can compensate the decrease in the potential of the first terminal due to the leak current.

Any of the above described NMOS buffer circuits is desired to show little fluctuations in the output voltage and obtain the necessary drive power while the drive circuit contained therein is protected against destruction.

### SUMMARY OF THE INVENTION

In view of the above circumstances, it is therefore an object of the present invention to provide a semiconductor circuit adapted to output a potential by way of source-follower-connected transistors with little fluctuations on the part of the output voltage.

Another object of the invention is to provide a semiconductor circuit adapted to output a potential by way of source-follower-connected transistors and hardly generate ringing noise.

Still another object of the invention is to provide a semiconductor circuit adapted to output a potential by way of source-follower-connected transistors and obtain the necessary drive power while preventing the elements of the drive circuit for driving the transistors from being subjected to an excessive potential.

In order to achieve an aspect of the present invention, a semiconductor circuit is composed of an N-channel transistor, a driving circuit, and a charge pump. The N-channel transistor includes a gate and a drain. The drain is provided with a power supply potential. The driving circuit sets a gate potential at the gate to a first potential in response to an input signal. The charge pump raises the gate potential to a second potential higher than the first potential in response to the input signal.

In this case, the N-channel transistor further may include a source from which an output current is outputted. The second potential is desirably selected such that the output current is maintained larger than a predetermined current.

The N-channel transistor may include a source from which an output signal is outputted. The first potential is desirably higher than a logical threshold potential for distinguishing a logical value of the output signal by a threshold voltage of the N-channel transistor.

In this case, the second potential is desirably selected such that an output current of the output signal is maintained larger than a predetermined current.

The semiconductor circuit may be further composed of an internal power supply circuit supplying to the driving circuit a stabilized potential lower than the power supply potential. The internal power supply circuit maintains the stabilized potential substantially constant.

In this case, the charge pump is desirably supplied with the stabilized potential to produce the second potential.

The driving circuit may include a capacitor element, a first transistor, a buffer, and a second transistor. The capacitor element has first and second terminals. The first transistor provides the first terminal with the stabilized potential in response to the input signal. The buffer is provided with the stabilized potential and outputs the stabilized potential to the second terminal in response to the second terminal. The second transistor connects the first terminal to the gate.

In this case, a capacitance of the capacitor element is selected based on a gate capacitance of the gate, the stabilized potential, and the first potential.

In order to achieve another aspect of the present invention, a method of operating a semiconductor circuit is composed of:

providing an N-channel transistor including a gate, a source, and a drain provided with a power supply potential;

setting the source to a predetermined potential; and

adjusting a gate-source voltage between the gate and the source such that a current outputted from the source is maintained larger than a predetermined current.

In order to achieve still another aspect of the present invention, a method of operating a semiconductor circuit including an N-channel transistor is composed of:

providing a drain of the N-channel transistor with a power supply potential;

setting a gate potential at a gate of the N-channel transistor to a first potential in response to an input signal;

supplying electric charges to the gate to raise the gate potential to a second potential higher than the first potential in response to the input signal; and

outputting an output signal from a source of the N-channel transistor in response to the gate potential.

In this case, the first potential is desirably higher than a logical threshold potential for distinguishing a logical value of the output signal by a threshold voltage of the N-channel transistor.

Also, the second potential is desirably selected such that an output current of the output signal is maintained larger than a predetermined current.

### BRIEF DESCRIPTION OF THE DRAWINGS

FIG. 1 is a circuit diagram of a known semiconductor circuit;

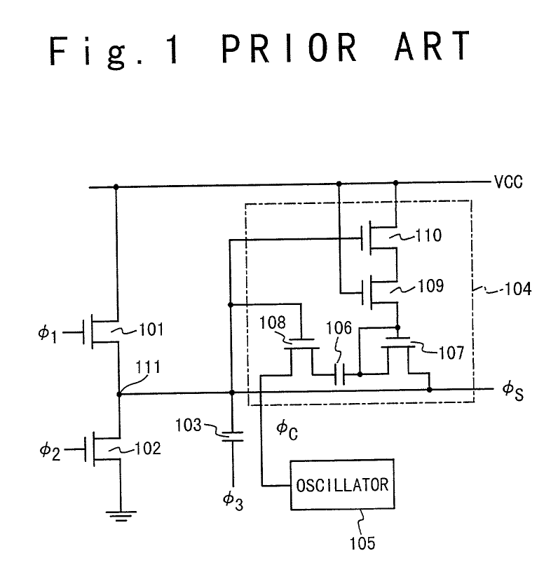

FIGS. 2A to 2E are timing charts of the signals of the known semiconductor circuit of FIG. 1;

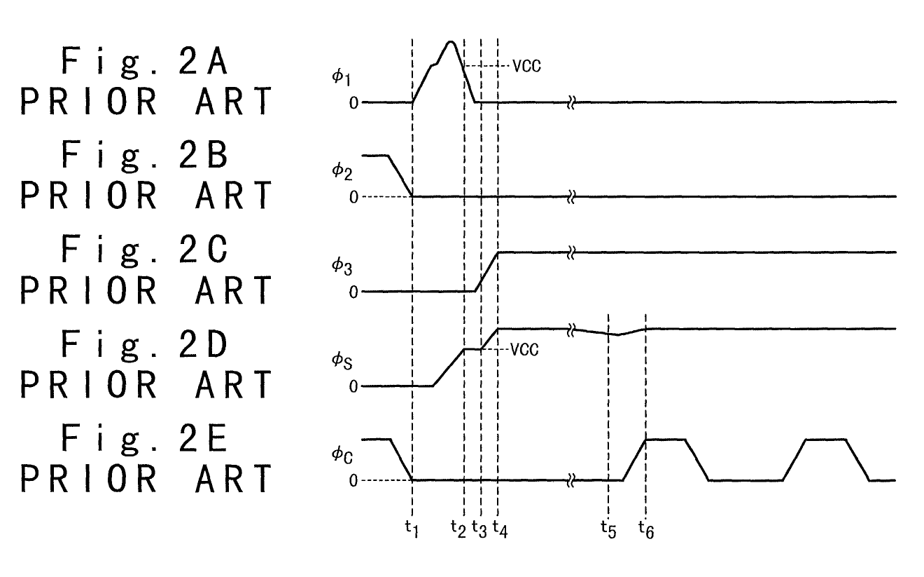

FIG. 3 is a circuit diagram of another known semiconductor circuit;

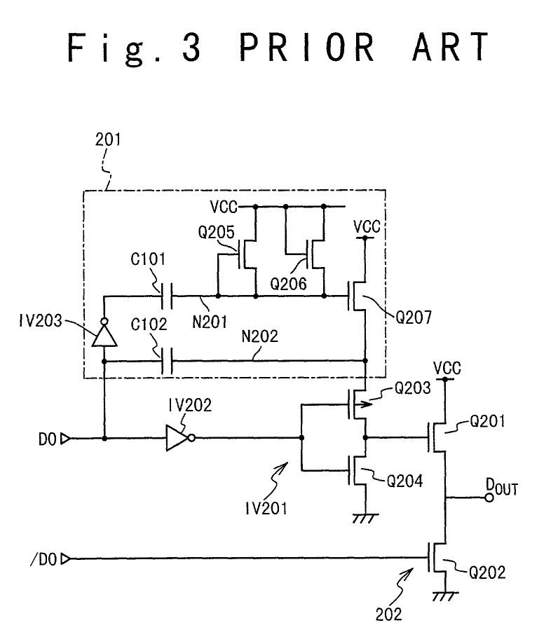

FIG. 4 is a circuit diagram of still another known semiconductor circuit;

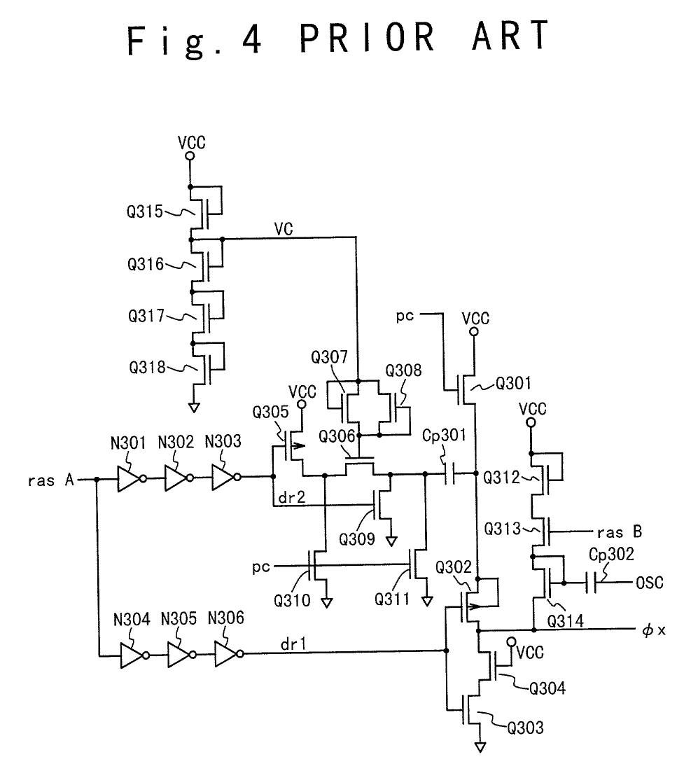

FIG. 5 is a circuit diagram of an embodiment of semiconductor circuit according to the invention; and

FIGS. 6A to 6F are timing charts of the signals for driving the first embodiment of semiconductor circuit of FIG. 5.

### DESCRIPTION OF THE PREFERRED EMBODIMENTS

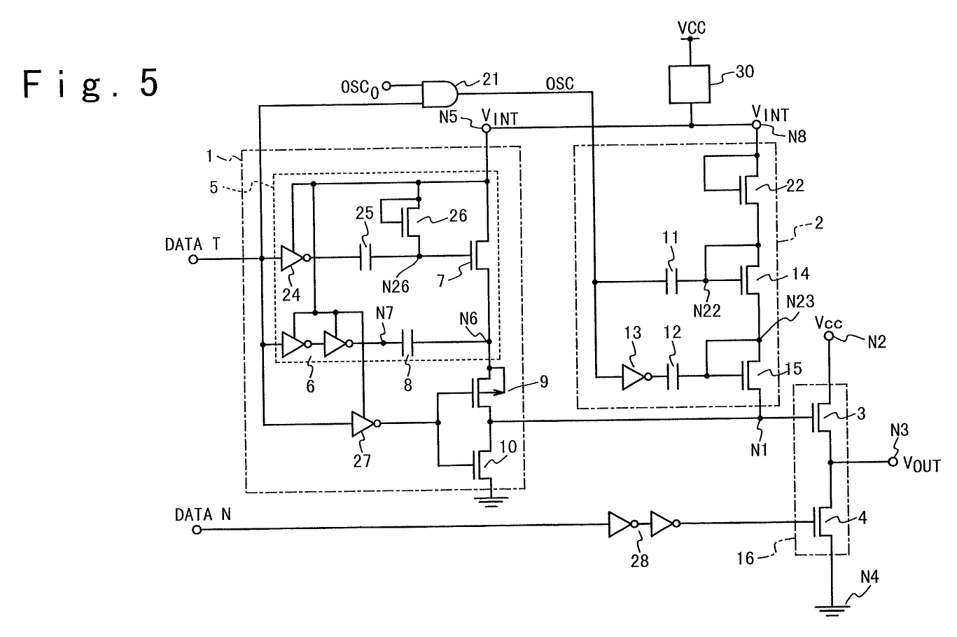

As shown in FIG. 5, a semiconductor circuit of an embodiment is provided with a drive circuit.

The drive circuit 1 is connected to a node N1. The drive circuit 1 is fed with potential V_{INT} from an internal power supply source 30. The internal power supply source 30 is fed with power supply potential V_{CC} and produces potential V_{INT} lower than power supply potential V_{CC}. The potential V_{INT} is held to a substantially constant level by the internal power supply source 30. The drive circuit 1 produces potential V₁ at node N₁ in response to an input signal DataT.

A charge pump circuit 2 is additionally connected to the node N1. After the drive circuit 1 produces potential V₁ at the node N1, the charge pump circuit 2 supplies the node N1 with electric charges to raise the potential of the node N1 to potential V₁ up to V₂.

An output circuit 16 is further connected to the node N1. The output circuit 16 includes MOS transistors 3 and 4. The MOS transistors 3 and 4 are n-channel MOS transistors. An output circuit 16 including only n-channel MOS transistors provides an advantage of being capable of producing a large drive power if compared with an output circuit comprising a CMOS inverter. The gate of the MOS transistor 3 is connected to the node N1. The drain of the MOS transistor 3 is connected to a power supply terminal N2, to which power supply potential V_{CC} is applied. The source of the MOS transistor 3 is connected to an output terminal N3. The output signal Vₒᵤₜ is outputted from the output circuit 16.

The drain of the MOS transistor 4 is additionally connected to the output terminal N3. The source of the MOS transistor 4 is connected to a grounding terminal N4, which is held to the ground potential. A Signal DataN that is complementarily relative to the input signal DataT is input to the gate of the MOS transistor 4 through a buffer 28. The MOS transistor 4 is turned off when the potential of the node N1 is raised and therefore the signal DataN is at the level “L”. On the other hand, the MOS transistor 4 is turned on when the node N1 is at the ground potential and therefore the signal DataN is at the level “H”.

Now, the drive circuit 1 will be described in detail. The drive circuit 1 includes a boosting circuit 5. The boosting circuit 5 includes a buffer 6, a MOS transistor 7, a capacitor 8, a p-channel MOS transistor 9, a MOS transistor 10, an inverter 24, a capacitance 25 and a MOS transistor 26.

The input signal DataT is input to the inverter 24. The inverter 24 outputs potential V_{INT} to one of the electrodes of the capacitance 25 in response to the input signal DataT. The other electrode of the capacitance 25 is connected to a node N26. The diode-connected MOS transistor 26 is connected between the node N26 and terminal N5 to which potential V_{INT} is applied. Furthermore, the gate of the MOS transistor 7 is connected to the node N26. The drain and the source of the MOS transistor 7 are connected respectively to the node N5 and to the node N6. The node N5 is provided with potential V_{INT}.

The boosting circuit 5 further includes a buffer 6. The buffer 6 outputs either the potential V_{INT} or the ground potential to the Node N7 according to the input signal DataT. The capacitor 8 is connected between the node N6 and the node N7. The capacitor 8 is used to produce potential V₁ at the node N6.

The p-channel MOS transistor 9 is arranged between the node N6 and the node N1. Input signal DataT is applied to the gate of the p-channel MOS transistor 9 through inverter 27. The p-channel MOS transistor 9 connects the node N1 and the node N6 depending on the input signal DataT. The node N1 and the node N6 are connected when the input signal DataT is at level “H” to make the potential of the node N1 equal to potential V₁. The node N1 and the node N6 are disconnected when the input signal DataT is at level “L”.

The MOS transistor 10 is arranged between the node N1 and the ground potential. The input signal DataT is applied to the gate of the MOS transistor 10 through the inverter 27. The MOS transistor 10 connects the node N1 to or disconnects the node N1 from the ground potential depending on the input signal DataT. The Node N1 is brought to the ground potential when the input signal DataT is at level “L”. Therefore, the MOS transistor 3 is turned off when the input signal DataT is at level “L”.

The drive circuit 1 operates in a manner as described below. When the input signal DataT is at level “H”, the output of the inverter 24 is at level “L”. Then, the MOS transistor 26 is turned on and the potential of the node N26 is brought to that of V_{INT}. The capacitance 25 is electrically charged by the potential difference V_{INT}.

If the potential of the input signal DataT is brought to level “L”, the potential of the node N26 becomes equal to 2×V_{INT} and the transistor 7 is turned on. Then, the potential N6 becomes equal to V_{INT}. On the other hand, the potential of the output of the buffer 6 is set to the level “L”. Thus, the capacitor 8 is electrically charged by the potential difference VINT.

Then, if the input signal DataT is brought to level “H”, the potential of the node N7 becomes equal to level “H” while that of the node N6 is made equal to 2×V_{INT}. Then, the p-channel MOS transistor 9 is turned on to connect the node 6 and the node N1. Thus, potential V₁ is produced at the node N1.

The potential V₁ is equal to that of the node N1 that appears after the electric charge accumulated in the capacitor 8 is delivered to the node N1 from the Node N6. The potential V₁ is expressed by the following formula,

$${V}_{1} = 2 {V}_{INT} \cdot \frac{{C}_{8}}{{C}_{8} + {C}_{N1}} . \qquad ( 1 )$$

Where C₈ is a capacitance of the capacitor 8, C_{N1} is a capacitance of the node N1.

The potential V₁ is determined in a manner as described below. The potential V₁ is determined based on a distinguishing potential V_{std}. The distinguishing potential V_{std} is defined as a potential that is referred to for logical distinguishing. The output terminal N3 is connected to some other circuit (not shown). The other circuit recognizes whether logical “1” or logical “0” is outputted based on the potential of the output terminal N3. If the potential is higher than the distinguishing potential V_{std}, the other circuit recognizes that logical “1” is outputted. Furthermore, the other circuit recognizes that logical “0” is outputted, if the potential is lower than the distinguishing potential V_{std}.

The potential V₁ is raised to a potential level higher than the lowest potential limit that can make the output voltage Vₒᵤₜ equal to level “H”. In other words, the potential V₁ is higher than the distinguishing potential V_{std} by more than the threshold voltage of the MOS transistor 3. As a result, if the potential of the input signal DataT is brought to level “H”, the potential of the output terminal N3 reliably gets to above the distinguishing potential V_{std} without waiting for the operation of the charge pump circuit 2.

Additionally, the potential V₁ is selected to a potential level that does not destroy any of the elements included in the drive circuit 1. With this arrangement, the potential V₁ is not necessarily higher than the power supply potential V_{CC} if the latter is high.

The potential V₁ is regulated by the capacitance of the capacitor 8 included in the boosting circuit 1. The capacitance of the capacitor 8 is determined on the basis of the capacitance C_{N1} of the node N1, the potential V_{INT} and the potential V₁. The load capacitance of the node N1 is the sum of the capacitance of the diffusion layer connected to the node N1 and the gate capacitance of the MOS transistor 3.

The capacitance C₈ of the capacitor 8 is so selected as to make the potential V₁ higher than the distinguishing potential V_{std} by more than the threshold voltage of the MOS transistor 3 by using the relationship as defined by the formula (1) above. It is desirable that the capacitance of the capacitor 8 is so selected as to make the potential V₁ higher than the sum of the distinguishing potential V_{std}, the threshold voltage of the MOS transistor 3 and an appropriate potential margin.

Additionally, it is also desirable that the capacitance of the capacitor 8 is selected to a minimal level that satisfies the above requirement because the chip size can be reduced by minimizing the capacitance of the capacitor 8.

Next, the charge pump circuit 2 will be described below. A periodic signal OSC₀ is supplied to an AND gate 21 from an oscillator (not shown). Then, the AND gate 21 outputs a periodic signal OSC so long as the input signal DataT is held to level “H”. Then, the capacitance 11 is fed with the periodic signal OSC only during periods when the input signal DataT is held to level “H”. The periodic signal OSC is a signal that is alternately and cyclically brought to potential level “L”, that is, ground potential and potential level “H”, that is, an internal power supply potential. The capacitance 12 is fed with the periodic signal OSC through an inverter 13.

When the periodic signal OSC is at potential level “L”, potential V_{INT} is applied to the capacitance 11 from terminal N8 through the diode-connected transistor 22. Then, electric charge is accumulated in the capacitance 11 at the side of node N22, which capacitance 11 comes to show a potential difference of V_{INT}.

Thereafter, when the periodic signal OSC is brought to potential level “H”, the capacitance 11 supplies the capacitance 12 with electric charge by way of MOS transistor 14 to bring the potential of node N23 to about 2×V_{INT}. Then, electric charge is accumulated in the capacitance 12 at the side of node N23.

Subsequently, as the periodic signal OSC is brought back to level “L”, the capacitance 12 supplies the node N1 with electric charge through the MOS transistor 15. In an ideal situation where the threshold voltage of MOS transistor is equal to 0 without load, the potential of the node N1 is made equal to 3×V_{INT}.

The potential V₂ of the node N1 produced by the charge pump circuit 2 is selected to such a level that it is higher than the potential V₁ and the output circuit 16 can reliably operate for driving. If a potential equal to the power supply potential V_{CC} is applied to the gate of the MOS transistor 3, the potential produced at the output terminal N3 is lower than the power supply potential V_{CC} by the threshold voltage of the MOS transistor 3. For outputting a potential close to the power supply potential V_{CC} in order to ensure a predetermined drive power, a potential higher than the power supply potential V_{CC} has to be applied to the gate of the MOS transistor 3. Therefore, the potential V₂ is selected to a level higher than the power supply potential V_{CC}. The level of the potential V₂ has to be made even higher when the power supply potential V_{CC} is low.

Furthermore, the level of the potential V₂ is determined according to the electric current that should be outputted from the output terminal N3. Assume that the potential of the gate of the MOS transistor 3 is raised to the level of the above-described potential V₁. The voltage between the gate and the source of the MOS transistor 3 at the moment when the potential of the gate of the MOS transistor 3 is raised to V₁ is sufficiently high for causing a necessary electric current to flow from the output terminal.

Assume then, the potential of the source of the MOS transistor 3 rises thereafter to get to the level of potential V₃, which is higher than the distinguishing potential V_{std}. If the potential of the gate of the MOS transistor 3 is maintained, the voltage between the gate and the source of the MOS transistor 3 becomes insufficient for causing the necessary electric current to flow from the output terminal. Therefore, the potential of the gate of the MOS transistor 3 is raised from V₁ to V₂. Thus, the level of the potential V₂ should be so selected that it ensures the necessary electric current to flow from the output terminal. This is the reason whey the level of the potential V₂ is determined as a function of the electric current that should be produced from the output terminal.

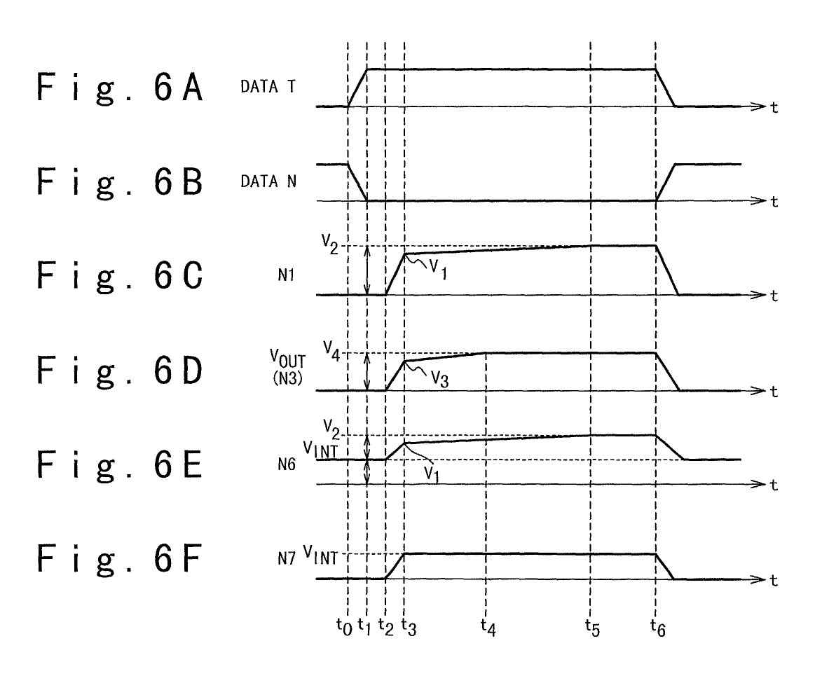

Now, the operation of this embodiment of semiconductor circuit according to the invention will be described below by referring to FIG. 6.

Time t<t₀:

Assume that the input signal DataT is at potential level “L” and the signal DataN is at potential level “H” at time t<t₀. Then, the output signal Vₒᵤₜ is at level “L”. Additionally, the MOS transistor 10 is turned on, and the potential of the node N1 is at level “L”. The buffer 6 produces a potential of level “L”, the potential of the node N7 is also at level “L”.

If the input signal DataT is at potential level “L”, the potential of the output of the inverter 24 is brought to level “H” to raise the potential of the node N26 to level “H”. The MOS transistor 7 is turned on. Thus, the node N6 is connected to the terminal N5 through the MOS transistor 7. Therefore, the potential of the node N6 is at potential V_{INT}. Since the potential of the node N7 is at level “L”, the capacitor 8 is electrically charged by the potential difference of V_{INT}.

time t₀≦t<t₃:

The input signal DataT starts rising at time t₀ and gets to potential level “H” at time t₁. Meanwhile, the signal DataN starts falling at time t₀ and gets to potential level “L” at time t₁.

After a certain delay time subsequent to the time t₀, that is, at time t₂ (t₁<t₂<t₃), the potential of the node N7 connected to the output of the buffer 6 starts rising until it gets to the level of V_{INT}. On the other hand, the potential of the node N6 starts rising from the level of V_{INT}. Substantially at the same time, the p-channel MOS transistor 9 is turned on so that electric charge is delivered to the node N1 from the node N6. The delivery of electric charge completes by time t₃. As a result, both the node N1 and the node N6 get to potential level V₁ at time t₃ while the output signal Vₒᵤₜ gets to potential level V₃. The potential V₃ is higher than the above-mentioned distinguishing potential V_{std}.

On the other hand, as the input signal DataT gets to potential level “H”, the charge pump circuit 2 starts operating. More specifically, the charge pump circuit 2 starts supplying electric charge to the node N1. Note that the time period between t₁ and t₃ is very short in reality. Therefore, the charge pump circuit 2 does not substantially do anything for raising the electric potential of the node N1 between during time t₀≦t<t₃.

time t₃≦t<t₅:

The charge pump circuit 2 keeps on supplying electric charge to the node N1. The potentials of the node N1 and the node N6 rise from level V₁ to level V₂. At time t₄, the potential of the output signal Vₒᵤₜ gets to level V₄, which is higher than level V₃.

time t₅≦t<t₆:

After time t₅, the potential of the node N1 is held to level V₂ and that of the output voltage Vₒᵤₜ is held to level V₄. The potential of the node N6 is same as that of the node N1 and hence held to level V₂.

time t≧t₆:

At time t₆, the potential of the input signal DataT returns to level “L” to turn off the p-channel transistor 9 and turn on the n-channel transistor 10. The potential of the node N1 gets back to level “L”. Additionally, the MOS transistor 3 is turned off while the MOS transistor 4 is turned on. Thus, the output voltage Vₒᵤₜ returns to potential level “L”. Additionally, the MOS transistor 7 is turned on and the potential of the node N6 gets to level V_{INT}. Then, the buffer 6 outputs potential “L” and the node N7 returns to potential level “L”.

This embodiment of semiconductor circuit produces an elevated potential at the node N1 depending on the input signal DataT. Then, the output terminal N3 can hardly generate ringing noise because the potential of the node N1 is raised in two steps, firstly to level V₁ by the drive circuit 1 and then to level V₂, which is the target potential level, by the charge pump current 2 so that overshooting can hardly occur at node N1. Thus, the output terminal N3 of the output circuit 16 connected to the node N1 can hardly generate ringing noise.

Additionally, with this embodiment of semiconductor circuit, the output voltage produced from the output terminal N3 is stable because the boosted potential produced at the node N1 that is connected to the gate of the transistor is stable. The drive circuit 1 produces potential V₁, using the internal power supply source 30 as power source. The potential VINT generated by the internal power supply source 30 is stabilized. Since the potential V1 is expressed by a formula (2)

$${V}_{1} = 2 {V}_{INT} \cdot \frac{{C}_{8}}{{C}_{8} + {C}_{N1}} , \qquad ( 2 )$$

the potential V₁ is stable if the potential V_{INT} is stable.

Still additionally, this embodiment of semiconductor circuit can prevent the elements of the drive circuit 1 from being destroyed because the drive circuit 1 is fed with the potential of the internal power supply source 30. Therefore, the elements of the drive circuit 1 are hardly exposed to any excessive potential.

On the other hand, this embodiment of semiconductor circuit can secure the necessary electric current from the output circuit 16 for the reason as described below. Immediately after the MOS transistor 3 is turned on, the gate and the source of the transistor shows a large potential difference and hence the necessary electric current can be secured by the relatively low potential V₁ produced from the drive circuit 1. After the rise of the electric potential of the source that operates as output terminal of the transistor, the potential of the gate of the MOS transistor 3 is raised to level V₂ by the charge pump circuit 2 so that the necessary electric current can also be secured. In this way, this embodiment of semiconductor circuit can secure the necessary electric current from the output circuit 16, while preventing the elements of the drive circuit 1 from being destroyed.

As described above in detail, a semiconductor circuit according to the invention is adapted to output a potential by way of source-follower-connected transistors with little fluctuations on the part of the output voltage. Additionally, a semiconductor circuit according to the invention is adapted to output a potential by way of source-follower-connected transistors and hardly generate ringing noise. Still additionally, a semiconductor circuit according to the invention is adapted to output a potential by way of source-follower-connected transistors and obtain the necessary drive power while preventing the elements of the drive circuit for driving the transistors from being subjected to an excessive potential.

Although the invention has been described in its preferred form with a certain degree of particularity, it is understood that the present disclosure of the preferred form has been changed in the details of construction and the combination and arrangement of parts may be resorted to without departing from the spirit and the scope of the invention as hereinafter claimed.

What is claimed is:

1. A semiconductor circuit comprising:
an N-channel transistor including a gate and a drain, wherein said drain is provided with a power supply potential;
a driving circuit setting a gate potential at said gate to a first potential in response to an input signal; and
a charge pump raising said gate potential to a second potential higher than said first potential in response to said input signal.

2. A semiconductor circuit according to claim 1, wherein said N-channel transistor further includes a source from which an output current is outputted, and said second potential is selected such that said output current is maintained larger than a predetermined current.

3. A semiconductor circuit according to claim 1, wherein said N-channel transistor further include a source from which an output signal is outputted, and
wherein said first potential is higher than a logical threshold potential for distinguishing a logical value of said output signal by a threshold voltage of said N-channel transistor.

4. A semiconductor circuit according to claim 3, wherein said second potential is selected such that an output current of said output signal is maintained larger than a predetermined current.

5. A semiconductor circuit according to claim 1, further comprising:
an internal power supply circuit supplying to said driving circuit a stabilized potential lower than said power supply potential, wherein said internal power supply circuit maintains said stabilized potential substantially constant.

6. A semiconductor circuit according to claim 5, wherein said charge pump is supplied with said stabilized potential to produce said second potential.

7. A semiconductor circuit according to claim 5, wherein said driving circuit includes:
a capacitor element having first and second terminals,
a first transistor providing said first terminal with said stabilized potential in response to said input signal,
a buffer provided with said stabilized potential and outputting said stabilized potential to said second terminal in response to said input signal, and
a second transistor connecting said first terminal to said gate.

8. A semiconductor circuit according to claim 7, a capacitance of said capacitor element is selected based on a gate capacitance of said gate, said stabilized potential, and said first potential.

9. A method of operating a semiconductor circuit comprising:
providing an N-channel transistor including:
a gate,
a source, and
a drain provided with a power supply potential;
setting said source to a predetermined potential; and
adjusting a gate-source voltage between said gate and said source such that a current outputted from said source is maintained larger than a predetermined current.

10. A method of operating a semiconductor circuit including an N-channel transistor, comprising:
providing a drain of said N-channel transistor with a power supply potential;
setting a gate potential at a gate of said N-channel transistor to a first potential in response to an input signal;
supplying electric charges to said gate to raise said gate potential to a second potential higher than said first potential in response to said input signal; and
outputting an output signal from a source of said N-channel transistor in response to said gate potential.

11. A method according to claim 10, wherein said first potential is higher than a logical threshold potential for distinguishing a logical value of said output signal by a threshold voltage of said N-channel transistor.

12. A method according to claim 10, wherein said second potential is selected such that an output current of said output signal is maintained larger than a predetermined current.
